(19) United States
(12) Patent Application Publication
(10) Pub. No.: US 2018/0277395 A1
(43) Pub. Date: Sep. 27, 2018

(54) METHOD FOR MANUFACTURING MULTILAYER CERAMIC SUBSTRATE

(71) Applicant: HITACHI METALS, LTD., Minato-ku,Tokyo (JP)

(72) Inventors: Junichi MASUKAWA, Minato-ku, Tokyo (JP); Hatsuo IKEDA, Minato-ku, Tokyo (JP)

(73) Assignee: HITACHI METALS ,LTD.

(21) Appl. No.: 15/755,567

(22) PCT Filed: Sep. 29, 2016
(86) PCT No.: PCT/JP2016/078866

§ 371 Date: Feb. 27, 2018

(30) Foreign Application Priority Data
Oct. 9, 2015 (JP) 2015-200751

(51) Int. Cl. H01L 21/48; H01L 23/498; H01L 23/13; B32B 18/00; B32B 37/10; B32B 37/06; B32B 38/10

(52) U.S. Cl. CPC H01L 21/4857; H01L 23/49827; H01L 23/49822; H01L 23/49838; H01L 23/13; H01L 24/48; B32B 18/00; B32B 37/10; B32B 37/06; B32B 38/10; H01L 21/486

(57) ABSTRACT

A method of producing a multi-layer ceramic substrate includes the steps of: (A) preparing a first ceramic green sheet with a thermal expansion layer arranged thereon, and at least one second ceramic green sheet with no thermal expansion layer arranged thereon; (B) laminating the first and second ceramic green sheets with the thermal expansion layer sandwiched therebetween, thereby obtaining a green sheet laminate; (C) pressure-bonding together the ceramic green sheets of the green sheet laminate; (D) heating and thereby expanding the thermal expansion layer in the pressure-bonded green sheet laminate; (E) extracting a portion of the green sheet laminate that has been displaced the expansion of the thermal expansion layer, thereby forming a cavity in the green sheet laminate; and (F) sintering the green sheet laminate with the cavity formed therein.

### TECHNICAL FIELD

The present invention relates to a method of producing a multi-layer ceramic substrate having a cavity.

### BACKGROUND ART

Multi-layer ceramic substrates have been widely used as wiring substrates for use in various electronic devices such as communication devices. Using a multi-layer ceramic substrate, it is possible to incorporate passive elements, such as capacitors, coils and transmission paths, into the substrate and implement electronic components on the surface of the substrate, thus realizing a small module. Moreover, in recent years, a cavity is provided in a multi-layer ceramic substrate and a semiconductor IC is accommodated in the cavity so as to achieve a low profile of the module as whole and to highly integrate and combine functions together.

Such a multi-layer ceramic substrate with a cavity is commonly produced by laminating and pressure-bonding together a ceramic green sheet having an opening corresponding to the cavity and a ceramic green sheet having no opening, and then sintering the ceramic green sheets. However, a ceramic green sheet having an opening is likely to deform when pressure-bonded.

In view of this, Patent Document No. 1 discloses a method of producing a multi-layer ceramic substrate with a cavity, wherein a ceramic green sheet laminate is produced by providing a peel-off layer sandwiched at a position to be the bottom of the cavity, making a slit that reaches the peel-off layer from one primary surface of the laminate before after the preliminary sintering (debindering process), removing a green sheet that corresponds to the cavity, and then sintering the laminate.

Patent Document No. 2 discloses a method of producing a multi-layer ceramic substrate with a cavity, wherein a ceramic green sheet laminate is produced by providing a burn-out material layer sandwiched at a position to be the bottom of the cavity, and grooving the laminate from one primary surface thereof before or after co-firing the laminate, so that the burn-out material layer is burnt out in the co-firing process, thus producing an internal space, whereby the cavity portion can be removed.

### CITATION LIST

### Patent Literature

[Patent Document No. 1] Japanese Laid-Open Patent Publication No. 2001-358247
[Patent Document No. 2] Japanese Laid-Open Patent Publication No. 2003-273267

### SUMMARY OF INVENTION

### Technical Problem

However, as a result of a study by the present inventor, it was found that it may not be easy in some cases to form a cavity by the methods of Patent Document Nos. 1 and 2. It is an object invention provide a method of producing a multi-layer ceramic substrate has a good mass productivity and with which it is possible to easily form a cavity.

### Solution to Problem

A method of producing a multi-layer ceramic substrate of the present invention includes the steps of: (A) preparing a first ceramic green sheet with a thermal expansion layer arranged thereon, and at least one second ceramic sheet with no thermal expansion layer arranged thereon; (B) laminating the first and second ceramic green sheets with the thermal expansion layer sandwiched therebetween, thereby obtaining a green sheet laminate; pressure-bonding together the first ceramic green sheet and the at least one second ceramic green sheet of the green sheet laminate; (D) heating and thereby expanding the thermal expansion layer at least in a thickness direction in the pressure-bonded green sheet laminate; (E) extracting a portion of the green sheet laminate that has been displaced by the expansion of the thermal expansion layer, thereby forming a cavity in the green sheet laminate; and (F) sintering the green sheet laminate with the cavity formed therein.

In the step (D), the thermal expansion layer may be held at a temperature higher than a temperature for pressure-bonding in the step (C).

The thermal expansion layer may include a thermal expansion material whose thickness increases by a factor of 2 or more by being heated.

The thermal expansion layer may be a layer of a paste including thermally-expansive microcapsules made of a thermoplastic resin that encapsulate a hydrocarbon that is in liquid form at normal temperature.

The method may further include, between the step (C) and the step (D), a step of forming, in the green sheet laminate, a groove that has a depth of the cavity of the green sheet laminate and defines an outline of the cavity.

The thermal expansion layer may be removed in the step (E).

In the step (A), a third ceramic green sheet with another thermal expansion layer arranged thereon may be prepared in a region different from the first ceramic green sheet; in the (B), the first to third ceramic green sheets may be laminated together so that the thermal expansion layers are sandwiched therebetween, thereby obtaining the green sheet laminate; in the step (D), the other thermal expansion layer may be heated to be expanded at least in the thickness direction; and in the step (E), a portion of the green sheet laminate that has been displaced by the expansion of the other thermal expansion layer may be extracted.

The method may further include, between the step (E) and the step (F), a step (G) of removing a binder from the green sheet laminate.

In the step (D), the thermal expansion layer may be held at a temperature that is higher than a temperature for pressure-bonding in the step (C) and lower than a temperature for binder removing in the step (G).

In the step (A), at least one of the first ceramic green sheet and the second ceramic green sheet may include a pattern to be internal wiring, an inductor, a condenser, a stripline or an internal resistor.

In the step (A), the first ceramic green sheet may further include a conductor pattern located between the thermal expansion layer and the first ceramic green sheet.

In the step (A), at least one of the first ceramic green sheet and the second ceramic green she m further include a via hole and a conductive paste that fills the via hole.

### Advantageous Effects of Invention

According to the present invention, there is provided a method of producing a multi-layer ceramic substrate which has a good mass productivity and with which it is easy to extract a portion corresponding to the cavity.

### BRIEF DESCRIPTION OF DRAWINGS

FIG. 1 (a) is a perspective view showing an example of a multi-layer ceramic substrate of the present embodiment, (b) is a cross-sectional view taken along line 1B-1B of (a), and (c) is a perspective view showing an example of a multi-layer ceramic substrate with a semiconductor IC chip mounted in the cavity.

FIG. 2 A flow chart showing d method of producing a multi-layer ceramic substrate of the present embodiment.

FIG. 3 (a) to (c) are process step cross-sectional views showing a method of producing a multi-layer ceramic substrate of the present embodiment.

FIG. 4 (a) to (d) are process step cross-sectional views showing the method of producing a multi-layer ceramic substrate of the present embodiment.

FIGS. 5 (a) and (b) are schematic diagrams showing, on an enlarged scale, the vicinity of an end portion of a thermal expansion lay illustrating the expansion of the thermal expansion layer and the separation of the portion to be the cavity.

FIG. 6 (a) is a cross-sectional view showing another example of a multi-layer ceramic substrate of the present embodiment, and (b) is a cross-sectional view showing one step of a method of producing the multi-layer ceramic substrate of (a).

FIG. 7 (a) is a cross-sectional view showing another example of a multi-layer ceramic substrate of the present embodiment, and (b) is a cross-sectional view showing one step of a method of producing the multi-layer ceramic substrate of (a).

FIG. 8 (a) is a cross-sectional view showing another example of a multi-layer ceramic substrate of the present embodiment, and (b) is a plan view of (a).

FIG. 9 A cross-sectional view showing one step of a method of producing the multi-layer ceramic substrate shown in FIG. 8.

FIG. 10 (a) is a cross-sectional view showing another example of a multi-layer ceramic substrate of the present embodiment, and (b) is a plan view of (a).

FIG. 11 (a) is a cross-sectional view showing another example of a multi-layer ceramic substrate of the present embodiment, and (b) is a plan view of (a).

FIG. 12 A graph showing the relationship between the temperature of the thermal expansion layer and the expansion factor for samples shown in Table 1.

FIGS. 13 (a) and (b) are optical microscopic images, before and after the expansion of the thermal expansion layer, of a green sheet laminate of a sample produced by a method of producing a multi-layer ceramic substrate of the present embodiment.

### DESCRIPTION OF EMBODIMENTS

The present inventor made an in-depth study on the methods manufacturing a multi-layer ceramic substrate disclosed in Patent Document Nos. 1 and 2. According to the methods of Patent Document Nos. 1 and 2, there is a need to form a slit or a groove reaching a peel-off layer or a burn-out layer in order to extract a portion of a green sheet corresponding to the cavity or a portion of a sinter corresponding to the cavity. It is difficult to separate the portion corresponding to the cavity unless the slit or groove is aligned with the position of the peel-off layer or burn-out layer and reliably extends to reach the peel-off layer or burn-out layer. Particularly, with the method of Patent Document No. 2, whether the portion corresponding to the cavity can be separated is known after the co-firing process, and it is therefore necessary to perform the manufacturing process up to the co-firing process even if it is a defective product.

According to the method of Patent Document No, since the peel-off layer is made of a material such that the ceramic green sheet can be peeled off easily, a green sheet laminate with the peel-off layer interposed therein will have an insufficient adhesion between the peel-off layer and the ceramic green sheet. Therefore, the pressure-bonded green sheet laminate may have an insufficient form stability or a green sheet may be shifted when forming a slit. With such problems described above, it may be difficult in some cases to stably manufacture a multi-layer ceramic substrate, thereby posing problems particularly in view of mass productivity. In view of such problems, the present inventor arrived at a novel method of producing a multi-layer ceramic substrate. One embodiment of a multi-layer ceramic substrate and a method of producing a multi-layer ceramic substrate of the present invention will now be described in detail. Note that a green sheet laminate as used in the description below is what is obtained by laminating first and second ceramic green sheets together, and every state from lamination until sintering is defined as a green sheet laminate, irrespective of the order and number of the sheets, the positions and number of thermal expansion layers, and the presence/absence of internal wiring or elements arranged inside the laminate.

[Structure of Multi-Layer Ceramic Substrate]

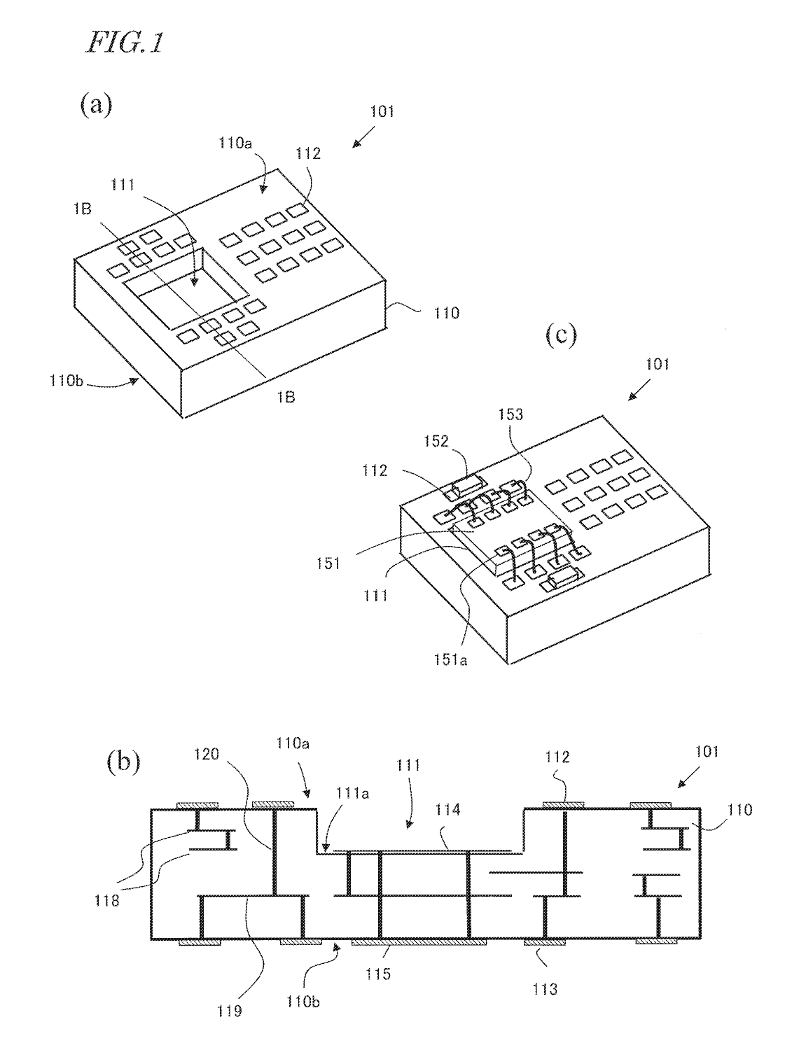

FIG. 1(a) is a perspective view showing an example of a multi-layer ceramic substrate of the present embodiment, and FIG. 1(b) shows a cross section taken along line 1B-1B of FIG. 1(a).

A multi-layer ceramic substrate 101 includes a ceramic sinter 110 having an upper surface 110a and a lower surface 110b. The upper surface 110a is provided with a cavity 111 for accommodating an electronic component such as a semiconductor IC chip. The cavity 111 has a recessed shape having an opening on the upper surface 110a. One electrode 112 or a plurality of electrodes 112 may be provided on the upper surface 110a. One electrode 113 or a plurality of electrodes 113 may be provided on the lower surface 110b. A heat-radiating electrode 114 is provided on a bottom portion 111a of the cavity 111 in order to radiate heat from the semiconductor IC accommodated in the cavity 111. While the multi-layer ceramic substrate 101 shown in FIG. 1 includes one cavity 111, the multi-layer ceramic substrate may include two or more cavities. In this case, bottom portions 111a may be at the same level or at different levels in two or more cavities 111, as will be described below.

A passive element pattern 118 and a conductive via 120 and a wiring pattern 119 may be provided inside the ceramic sinter 110. The passive element pattern 118 may have a conductivity or a predetermined resistance value, for example, and may form internal wiring, an inductor, a condenser, a stripline, an internal resistor, or the like.

The wiring pattern 119 is made of a conductive thin-layer pattern that is generally parallel to the upper surface 110a and the lower surface 110b. The conductive via 120 is made of a via hole extending in a direction connecting between the upper surface 110a and the lower surface 110b, and a columnar-shaped conductor filling the via e. The wiring pattern 119 and the conductive via 120 are connected to the passive element pattern 118, the wiring pattern 119, the electrode 112, the electrode 113, the electrode 114, etc., thereby forming a predetermined circuit.

As shown in FIG. 1(b), the conductive via 120 connected to the heat-radiating electrode 114 may reach the lower surface 110b as a radiator. A heat-radiating electrode 115 that is connected to the conductive via 120 connected to the heat-radiating electrode 114 may be further provided on the lower surface 110b.

The multi-layer ceramic substrate 101 may be a low temperature co-fired ceramic (LTCC) substrate or a high temperature co-fired ceramic (HTC substrate. A ceramic material and a conductive material suitable for the sintering temperature, the application, etc., are used for the ceramic sinter 110, the passive element pattern 118, the wiring pattern 119, the electrode 112, the electrode 113 and the electrode 114. When the multi-layer ceramic substrate 101 is a low temperature co-fired multi-layer ceramic substrate, a ceramic material and a conductive material that can be sintered in a temperature range of about 800° C. to about 1000° C. are used. For example, the ceramic material used may be a ceramic material including Al, Si and Sr as its main components and Ti, Bi, Cu, Mn, Na and K as its sub-components, a ceramic material including Al, Si and Sr as its main components and Ca, Ph, Na and K as its sub-components, ceramic material including Al, Mg, Si and Gd, and a ceramic material including Al, Si, Zr and Mg. The conductive material used may be a conductive material including Ag or Cu. The dielectric constant of the ceramic material is about 3 to about 15. When the multi-layer ceramic substrate 101 is a high temperature co-fired multi-layer ceramic substrate, a ceramic material including Al as its main components, and a conductive material including W (tungsten) or Mo (molybdenum) may be used.

There is no particular limitation on the size of the multi-layer ceramic substrate 101. The multi-layer ceramic substrate 101 may be produced in a size that is suitable for the application, the number of passive elements included therein, the circuit scale, the size and number of cavities 111, etc.

FIG. 1(c) shows a state where a semiconductor IC chip and a capacitor are mounted on the multi-layer ceramic substrate 101. As shown in FIG. 1(c), a semiconductor IC chip 151 is arranged in the cavity 111. For example, the semiconductor IC chip 151 is secured, facing up, by a solder, a heat-conductive adhesive, etc. Electrodes 151a of the semiconductor IC chip 151 and the electrodes 112 of the multi-layer ceramic substrate 101 are connected together by bonding wires 153. A passive element or an active element that can be surface-mounted, such as a capacitor 152, for example, may be connected to the electrode 112 by a solder. Although not shown in the figures, the semiconductor IC chip 151 may be mounted, facing down, in the cavity 111. In such a case, electrodes corresponding to the electrodes of the semiconductor IC chip 151 are provided on the bottom surface of the cavity 111, and the electrodes on the bottom surface of the cavity 111 are connected to the electrodes of the semiconductor IC chip 151 by reflow soldering, or the like.

[Method for Manufacturing Multi-Layer Ceramic Substrate]

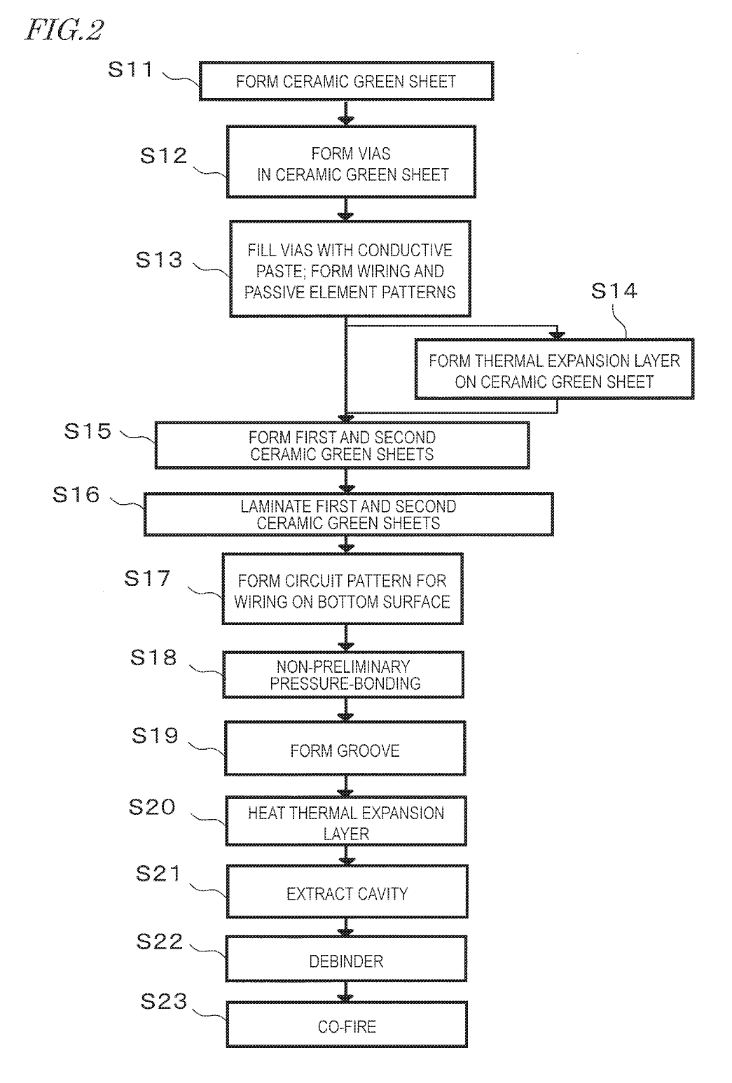

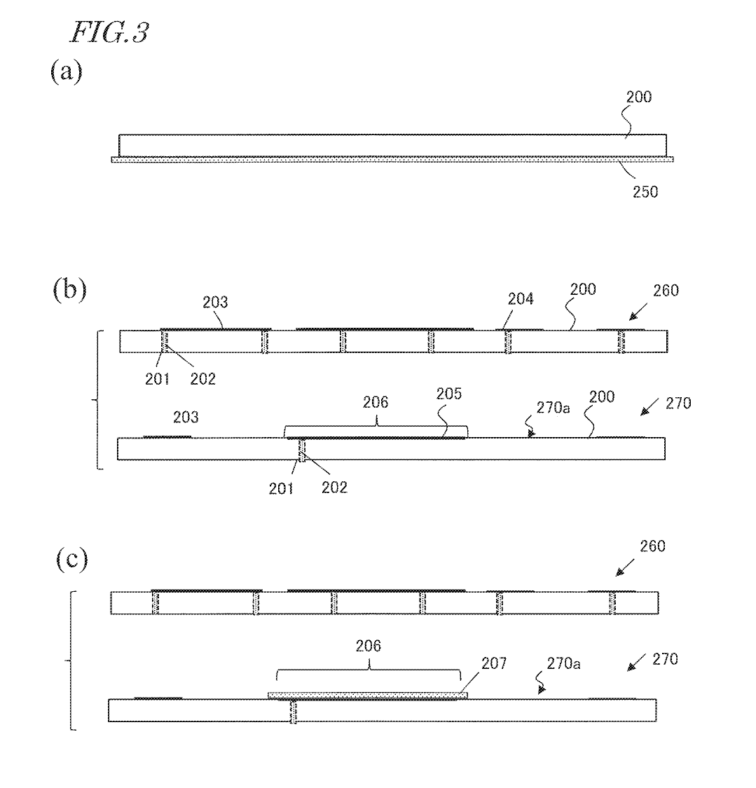

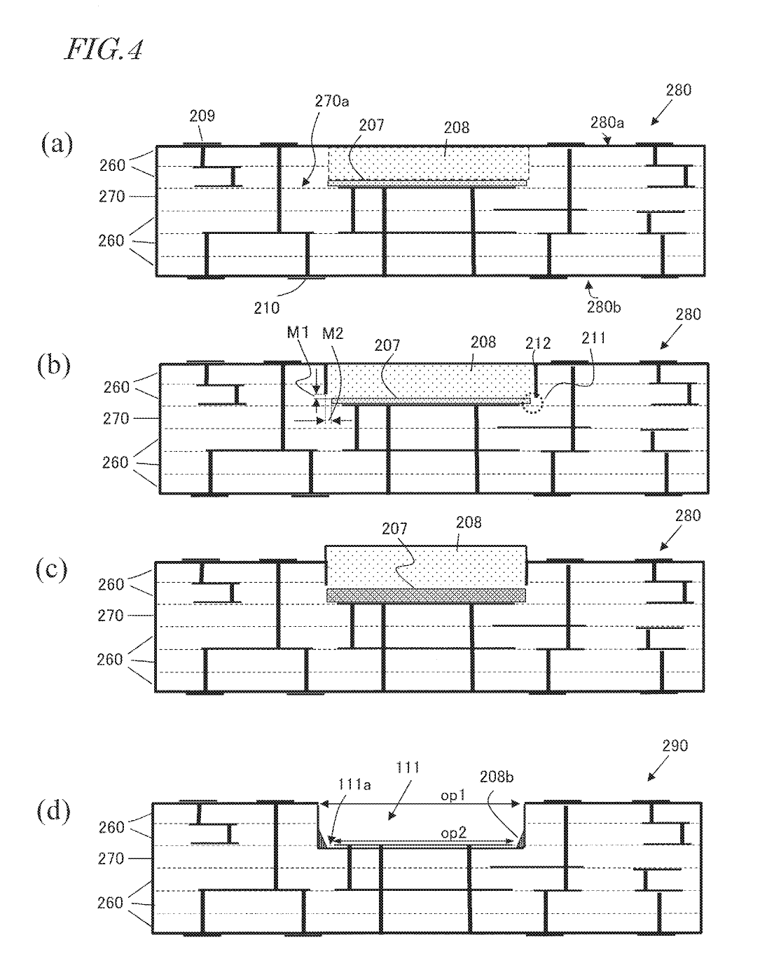

A method of producing a multi-layer ceramic substrate will be described. FIG. 2 is a flow chart showing a method of producing a multi-layer ceramic substrate. FIG. 3 and FIG. 4 are process step cross-sectional views showing a method producing multi-layer ceramic substrate. Referring to FIG. 2, FIG. 3 and FIG. 4, a method of producing a multi-layer ceramic substrate of the present embodiment will be described. The following description is directed to an example where ceramic green sheets are laminated together to form one multi-layer ceramic substrate, but two or more multi-layer ceramic substrates may be formed.

1. Step of Preparing First and Second Ceramic Green Sheets

(1) Preparation of Ceramic Green Sheets

First, a ceramic material is prepared. A ceramic material including elements as described above is prepared and subjected to preliminary sintering at 700° C. to 850° C., for example, as necessary, and pulverized into grains. A glass component powder, an organic binder, a plasticizer and a solvent are added to the ceramic material, thereby obtaining a slurry of the mixture. A powder of the conductive material described above is mixed with an organic binder and a solvent, etc., thereby obtaining a conductive paste.

A layer of the slurry having a predetermined thickness is formed on a carrier film 250 by using a doctor blade method, a rolling (extrusion) method, a printing method, an inkjet application method, a transfer method, or the like, and the layer is dried. The dried slurry layer has a thickness of 20 μm to 200 μm, for example. The slurry layer is severed to obtain a plurality of ceramic green sheets 200 as shown in FIG. 3(a) (S11).

(2) Formation of Via Pattern, Wiring Pattern, Passive Element Pattern

As shown in FIG. 3(b), in accordance with a circuit to be formed in the multi-layer ceramic substrate, via holes 201 are formed in the plurality of ceramic green sheets 200 by using a laser, a mechanical puncher, or the like, (S12), and the via holes 201 are filled with a conductive paste 202 by using a screen printing method 3). A conductive paste is printed on the ceramic green sheets by using a screen printing, or the like, to form a wiring pattern 203 and a passive element pattern 204 on the ceramic green sheet 200 (S13). The diameter of the via holes 201 is 60 μm to 100 μm, for example, and the thickness of the wiring pattern 203 and the passive element pattern 204 is 5 μm to 35 μm, for example. The via pattern, the wiring pattern and the passive element pattern to be formed may vary for each green sheet depending on the position (level) of the ceramic green sheet 200. The plurality of ceramic green sheets 200 are classified into first ceramic green sheets 270 and second ceramic green sheets 260. The first ceramic green sheet 270 has a primary surface 270a to be the bottom surface of the cavity, and a region 206 to be the bottom surface of the cavity is located on the primary surface 270a. An electrode pattern 205 of a heat-radiating electrode may be formed in the region 206. No thermal expansion layer is formed on the second ceramic green sheet 260.

(3) Preparation of Thermal Expansion Layer

A thermal expansion layer whose thickness increases when heated is prepared. The thermal expansion layer may have a sheet shape and may be cut into pieces of a desired shape, or a thermal expansion layer paste may be prepared and the thermal expansion layer may be formed by printing using screen printing, or the like. When a thermal expansion layer paste is used, screen printing can be used, and patterns to be formed can easily be aligned with each other. In such a case, there are advantages such as being able to freely and easily determine the shape of the thermal expansion layer, being able to easily adjust the thickness thereof, etc.

The thermal expansion layer includes a thermal expansion material that expands when heated. The expansion of the thermal expansion material increases the thickness of the thermal expansion layer, thereby displacing a portion of the ceramic green sheet that is located over the thermal expansion layer. It is preferred that the thickness of the thermal expansion layer increases when heated, and it is preferred that the thickness increases by factor of 2 more. That is, it is preferred that the expansion factor is 2 or more. It, is more preferred that, the thickness of the thermal expansion layer increases when heated by a factor 2 or more and 12 or less, example.

For example, the thermal expansion layer paste includes thermally-expansive microcapsules made of a thermoplastic resin that encapsulate a hydrocarbon that is in liquid form at normal temperature as the thermal expansion material, and includes organic materials such resin and a solvent. The thermally-expansive microcapsules have an average particle size of 5 μm to 50 μm, for example, and each include an outer shell made of a thermoplastic resin and a low boiling hydrocarbon filling the inside of the outer shell that is in liquid form at normal temperature. When heated at a temperature in the range of about 70° C. to about 260° C., for example, the low boiling hydrocarbon evaporates and the outer shells soften at the same time, thereby forming independent hollow bubbles. That is, the microcapsules expand. For example, expansive microcapsules of various average particle sizes, thermal expansion start temperatures and maximum expansion temperatures are commercially available, and they can be used. Preferably, the thermally-expansive microcapsule is selected so that the thickness of the thermal expansion layer reaches its maximum at a temperature that is higher than the heating temperature for final pressure-bonding to be described below and lower than the heating temperature for debindering. For example, when 80° C. is selected as the heating temperature for final pressure-bonding and 350° C. the heating temperature for debindering, the thermal decomposition of the binder, and the like, starts when the temperature increases past about 200° C. Therefore, the thermally-expansive microcapsule to be selected for use in the thermal expansion layer is designed so that the thermal expansion layer expands at a temperature of 80° C. or more and 200° C. or less and reaches its maximum volume preferably at about 100° C. to about 150° C. Then, it is possible to expand the thermal expansion layer without inhibiting the pressure-bonding of the ceramic green sheets during the final pressure-bonding process and while the binder is included in the green sheet laminate. Thus, it is possible to avoid the problem that the green sheet laminate becomes brittle because the binder is removed when forming the cavity, making it difficult to handle the green sheet laminate.

The average particle size of the thermally-expansive microcapsules may influence the flatness of the bottom portion 111a of the cavity 111. When there is a need for a smoother bottom portion 111a, it is preferred to use thermally-expansive microcapsules having an average particle size that is as small as possible an the range described above, e.g., 10 μm, so that the unevenness of the bottom portion of the cavity 111 is reduced and the bottom portion becomes smooth. Moreover, in order to reduce the unevenness of the bottom surface of the cavity formed, an unevenness improving material having a size smaller than the thermal expansion material so as to fill the gaps may be added to the expansion layer paste. For example, acrylic beads, or the like, may be used as the unevenness improving material.

(4) Formation of Thermal Expansion Layer

The thermal expansion layer is arranged on the first ceramic green sheet 270. As shown in FIG. 3(c), a thermal expansion layer 207 is formed in the region 206 to be the bottom surface of the cavity on the primary surface 270a of the first 270 (S14). As described above, a sheet-shaped thermal expansion layer 207 may be arranged, or the thermal expansion layer 207 may be formed by, for example, screen printing a paste. No thermal expansion layer is arranged on the second ceramic green sheet 260. Thus, a first ceramic green sheet 270 with a thermal expansion layer arranged thereon and at least one second ceramic green sheet 260 with no thermal expansion layer arranged thereon are prepared (S15). The thickness of the thermal expansion layer 207 is preferably 10 μm or more and 50 μm or less. If the thermal expansion layer is thinner than the thermally-expansive microcapsules, the thermally-expansive microcapsules sink into the ceramic green sheets, thereby deforming the ceramic green sheets. If the thermal expansion layer is too thick, it will inhibit the pressure-bonding between the ceramic green sheets. The thickness of the thermal expansion layer 207 is preferably greater than or equal to the average particle size of the thermally-expansive microcapsules.

In the present embodiment, since the multi-layer ceramic substrate 101 includes one cavity 111, one thermal expansion layer 207 is arranged on the first ceramic green sheet 270 in FIG. 3(c). When the multi-layer ceramic substrate 101 includes two or more independent cavities 111 having their bottom surfaces at the same level, the thermal expansion layer 207 provided in each of the regions to be the bottom surfaces of the two or more independent cavities 111.

2. Step of Obtaining Green Sheet Laminate

The first and second ceramic green sheets 270 and 260 are sequentially laminated together with preliminary pressure-bonding therebetween, thereby forming a green sheet laminate (S16). The second ceramic green sheets 260 and the first ceramic green sheet 270 described above are sequentially laminated together with preliminary pressure-bonding therebetween so as to form a circuit as designed. The total number of layers of the first and second ceramic green sheets 270 and 260 in a green sheet laminate 280 is 4 to 20, for example. The procedure of preliminary pressure-bonding and lamination is in accordance with an ordinary method of producing a multi-layer ceramic substrate. The lamination of the first and second ceramic green sheets 270 and 260 may be performed under a reduced pressure to make it easier to remove bubbles between sheets.

In order to form the space of the cavity 111, one or more second ceramic green sheet 260 is laminated on the first ceramic green sheet 270 with the thermal expansion layer sandwiched therebetween. The second ceramic green sheet 260 may be arranged also under the first ceramic green sheet 270 to ensure the strength of the bottom of the cavity 111 to arrange the above-described circuit: thereon.

Thus, the green sheet laminate 280 is obtained as shown in FIG. 4(a). In this process, the first ceramic green sheet 270 is arranged so that the primary surface 270a of the first ceramic green sheet 270 is located at a level (i.e., a height position in the lamination direction of the green sheet laminate) that is to be the bottom portion of the cavity.

While the multi-layer ceramic substrate 101 includes one cavity 111 in the present embodiment, it may include two or more cavities. When the multi-layer ceramic substrate includes two or more cavities 111 having different bottom surface levels, two or more first ceramic green sheets 270 are arranged so that the primary surface 270a of each of the two or more first ceramic green sheets 270 is located t a level (i.e., a height position in the lamination direction of the green sheet laminate) that is to be the bottom portion of the corresponding cavity.

The thermal expansion layer 207 is located in a region to be the bottom portion of a portion 208 to be the cavity. The portion 208 to be the cavity is a part of the second and/or first ceramic green sheet until it is separated by a groove 212 or the thermal expansion layer 207.

As necessary, an electrode pattern 209 and an electrode pattern 210 are formed on an upper surface 280a and a lower surface 280b, respectively, of the green sheet laminate 280 (S17). An overcoat material may be further arranged around the electrode pattern 209 and the electrode pattern 210.

3. Final Pressure-Bonding Step

Next, the first and second ceramic green sheets 270 and 260 of the green sheet laminate 280 are pressure-bonded together (S18). For example, the green sheet laminate 280 is set in a frame, and the final pressure-bonding is performed by using a cold isostatic pressing (CIP) device, or the like. The entire green sheet laminate 280 may be heated during the final pressure-bonding so that the resin in the first and second ceramic green sheets 270 and 260 and the gluing agent in the conductive paste are softened to adhere with each other. For the heating, it is preferred to use a temperature such that the thermal expansion layer 207 does not expand. The temperature at which the thermal expansion layer 207 starts expanding dictated primarily by the characteristics of the thermally expansive microcapsules included in the thermal expansion layer 207. For example, the entire green sheet laminate 280 is heated in a temperature range of 60° C. to 90° C.

4. Groove Forming Step

The groove 212 is formed on the green sheet laminate 280 for extracting the portion 208 to be the cavity (S19). Specifically, the groove 212 having a depth from the upper surface 280a along the lamination direction of the green sheet laminate 280 is formed so as to extend along the outline of the portion 208 to be the cavity as shown in 4(b). The groove 212 may be formed by laser machining using YAG, or the like, or by punching using a blade shape of a knife cutter, or the like. The width of the groove 212 is preferably 10 μm to 200 μm, for example. When the width of the groove 212 is less than 10 μm, the two opposing side surfaces that define the groove 212 may deform and come into contact with each other due to some external force after the formation of the groove 212. When the side surfaces come into contact with each other, it may become difficult to extract the portion 208 to be the cavity.

The groove 212 may not reach the thermal expansion layer 207 but may have a depth with a margin M1 in the lamination direction of the green sheet laminate 280. That is, the bottom portion of the groove 212 and the thermal expansion layer 207 may be separated from each other by the margin M1 in the lamination direction. When the groove 212 runs through the thermal expansion layer 207 and reaches a ceramic green sheet that is located below the thermal expansion layer 207, the groove 212 located below the thermal expansion layer 207 remains after sintering the green sheet laminate 280, even after the extraction of the portion 208 to be the cavity and the removal of the thermal expansion layer 207. Such a groove will lower the strength of the multi-layer ceramic substrate obtained by sintering. With the provision of the margin M1, it is possible to prevent the groove 212 from running through the thermal expansion layer 207 because of the precision of the device for forming the groove 212 being insufficient, variations in the formation of the groove 212, etc. Similarly, the groove 212 may have a margin M2 from the end portion of the thermal expansion layer 207 in the horizontal direction (the direction perpendicular to the lamination direction of the green sheet laminate 280).

Note that although the groove 212 for extracting the portion 208 to be the cavity is provided in the green sheet laminate 280 in the present embodiment, the groove 212 may be absent when the depth of the cavity to be formed is as small as 50 μm or less.

As described above, when the green sheet laminate forms a large substrate that a collection of multi-layer ceramic substrates 101, separation grooves for separating into individual substrates after sintering may be similar) y formed at this point by using a knife cutter, or the like.

5. Step of Expanding Thermal Expansion Layer

The thermal expansion layer 207 is expanded by heat (S20). Specifically, the green sheet laminate 280 is held at a temperature such that the thickness of the thermal expansion layer 207 increases. This temperature is higher than the heating temperature for final pressure-bonding and lower than the heating temperature for debindering. For example, the green sheet laminate 280 is held at a temperature in the range of 110° C. or more and less than 200° C. for 1 min or more and 30 min or less Preferably, the holding temperature is 150° C. or less. Herein, in order to remove the binder after the expansion of the thermal expansion layer, the upper limit of the temperature for expanding the thermal expansion layer 207 is set to a temperature that is lower than the temperature at which the binder starts to be removed. However, the thermal expansion layer may be expanded after the debindering step or during the debindering step. In such a case, the thermal expansion layer may be expanded at a higher temperature.

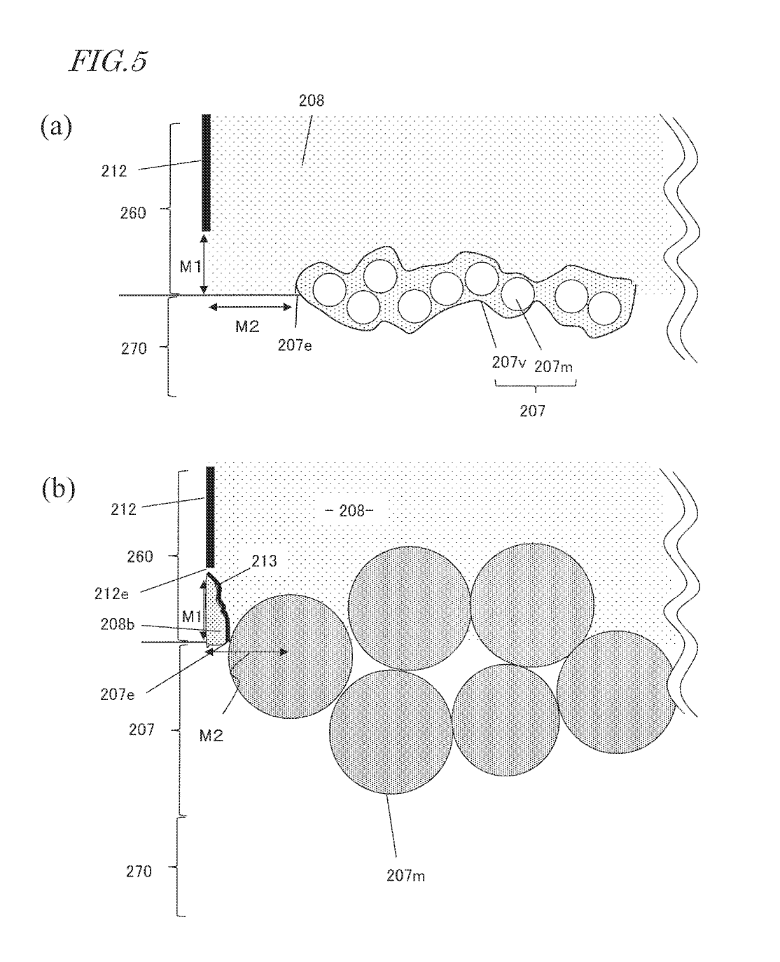

FIGS. 5(a) and 5(b) are schematic diagrams showing, on an enlarged scale, the vicinity of the end portion of the thermal expansion layer 207 for illustrating the expansion of the thermal expansion layer 207 and the separation of the portion 208 to be the cavity. In FIG. 5, different elements are scaled differently for the sake of illustration, and the figure does not represent the actual scale. The thermal expansion layer 207 is present in a state where thermal expansion layer microcapsules 207m and an organic material 207v are mixed together until the expansion of the thermal expansion layer 207 after the final pressure-bonding step. As described above, there may be the margin M2 in the horizontal direction so that an end portion 207e of the thermal expansion layer 207 is located on the inner side of the opposite ends of the portion 208 to be the cavity in order to avoid a crack extending continuous from the bottom portion of the cavity. In the lamination direction of the green sheet laminate 280, there may be the margin M1 provided between the groove 212 and the thermal expansion layer 207. The thermal expansion layer microcapsules 207m are bonded to the portion 208 to be the cavity and the first ceramic green sheet 270 by means of the organic material 207v.

In the process of increasing the temperature from this bonded state, the organic material 207v, the binder of the ceramic green sheets, etc., become soft, while the thermal expansion layer microcapsules 207m expand, thereby losing the adhesion. Therefore, peeling occurs between the thermal expansion layer microcapsules 207m and the portion 208 to be the cavity and between the thermal expansion layer microcapsules 207m and the first ceramic green sheet 270. Moreover, as the thermal expansion layer microcapsules 207m expand, the surrounding first and second ceramic green sheets are pushed apart from each other. As a result, the portion 208 to be the cavity and the first ceramic green sheet 270, which have been bonded together with the thermal expansion layer 207 interposed therebetween, peel off and come off the thermal expansion layer 207.

Thus, the thickness of the thermal expansion layer 207 increases as shown in FIG. 4(c). In this process, as shown in FIG. 5(b), when at least one of the margin M1 and the margin M2 is provided between the end portion 207e of the thermal expansion layer 207 and a bottom portion 212e of the groove 212, the portion 208 of the ceramic green sheet to be the cavity remains connected to the rest in a portion 211 where the margin M1 and the margin M2 are provided. However, as the thermal expansion layer microcapsules 207m expand, a shear stress acts on the portion 211 due to the displacement of the portion 208 to be the cavity and the stress from the expansion of the thermal expansion layer microcapsules 207m.

As a result, in the portion 211 where the margin M1 and the margin M2 are provided, there occurs a crack 213 starting from the bottom portion 212e of the groove 212 and reaching the interface between the first ceramic green sheet 270 and the second ceramic green sheet 260 or the thermal expansion layer 207 (the thermal expansion layer microcapsules 207m). Thus, the entire outline of the portion 208 to be the cavity is separated from the green sheet laminate 280. As a result, a gap is formed between the two ceramic green sheets that sandwich the thermal expansion layer 207 therebetween, and the portion 208 to be the cavity is lifted and displaced by the thermal expansion layer 207. In this process, as shown in FIG. 5(b), if the direction in which the crack 213 extends is not perpendicular to the laminating surface of the green sheet, a part of the portion 208 to be the cavity remains as burrs 208b.

6. Cavity Forming Step

As shown in FIG. 4(c), by extracting the portion 208 to be the cavity displaced by the expansion of the thermal expansion layer 207, the cavity 111 is formed in the green sheet laminate 280 (S21). The side surface of the portion 208 to be the cavity is completely separated from the green e laminate 280. Moreover, as the thermal expansion layer 207 expands and the adhesive strength lowers, there occurs a gap also between the thermal expansion layer 207 and the portion 208 to be the cavity and between the thermal expansion layer 207 and the green sheet laminate 280. Therefore, by holding the green sheet laminate 280 with the upper surface 280a facing down, the portion 208 to be the cavity drops off the green sheet laminate 280 by virtue of its own weight, thus obtaining a green sheet laminate 290 provided with the cavity 111 having an opening on the upper surface 280a. If the portion 208 to be the cavity does not easily drop by virtue of its own weight because of the groove width being small, the portion 208 to be the cavity may be removed by using a tape, a suction head, or the like.

In this process, a part or whole of the thermal expansion layer 207 may come off together with the portion 208 to be the cavity, or the entire thermal expansion layer 207 may remain stuck on the bottom of the cavity 111. That is, a part or whole of the thermal expansion layer 207 may be removed together with the portion 208 to be the cavity. If a part or whole of the thermal expansion layer 207 remains in the green sheet laminate 280, most of it disappears in the debindering step to be described below. The thermal expansion layer 207 that does not disappear in the debindering step can be made to disappear in the sintering step. If there is a portion that remains after the sintering step, it may be immersed in an acid, an alkali or a fluoride after the sintering step, and it may be further cleaned by using ultrasonic waves, etc., as necessary. When the thermal expansion layer includes a portion that remains after the sintering step as described above, a pretreatment of cleaning a thermal expansion material, etc., may be performed before forming the thermal expansion layer by using a thermal expansion layer paste including the thermal expansion material.

As described above, depending on the lengths of the margin M1 and the margin M2, the crack 213 occurs in a slant direction with respect to the lamination direction of the ceramic green sheets, and the burrs 208b occur on the bottom portion 111, of the cavity 111. When the burrs 208b occur, the length op2 of a flat bottom portion 111b is shorter than the length of the opening op1 of the cavity 111, as shown in FIG. 4(d).

7. Debindering Step

The binder is removed from the green sheet laminate 290 having the cavity 111 (S22). Specifically, organic components such as a resin and a solvent included in the green sheet laminate 290 are heated and removed. For example, held at a temperature in the range of 200° C. or more and 600° C. s for 120 min or more and 600 min or less. The holding temperature may be constant or may be varied. For example, the green sheet laminate 290 may be heated 500° C., and then it may be cooled gradually or the holding temperature may be lowered gradually. Through this step, the resin, the solvent and the thermal expansion layer 207 included the sheet 290 disappear (evaporate). For example, the thermal expansion layer 207 disappears at a temperature in the range of about 350° C. to 600° C. It was found that if the temperature range is the same as the debindering temperature range, it is possible to expand the thermal expansion layer during the debindering step, described above, and to cause most of the remaining thermal expansion layer to disappear during the debindering after the cavity is formed. Moreover, if there remain traces of the thermal expansion material on the bottom surface of the cavity formed, a material that disappears in this temperature range can be used, as an unevenness improving material, to fill the gaps in the thermal expansion material. The unevenness improving material may be acrylic beads, or the like.

This debindering step may be performed successively after the step of expanding the thermal expansion layer, and the cavity may be formed after the debindering step. By successively performing the two steps, it is possible to shorten the manufacturing process.

In the debindering step, since the binder is removed and the green sheet laminate becomes brittle, the thermal expansion layer may be expanded after the debindering step to remove the portion to be the cavity, thereby forming the cavity. In such a case, it is preferred that the green sheet laminate is held at a temperature such that the thermal expansion layer does not expand in the debindering step.

8. Sintering Step

The debindered green sheet laminate 290 is sintered (S23). Specifically, the green sheet laminate 290 is held at a sintering temperature for the ceramic included in the ceramic green sheet, thereby sintering the ceramic. For example, it is held at a temperature in the range of 850° C. or more and 940° C. s for 100 min or more and 180 min or less. Thus, it is possible to obtain a multi-layer ceramic substrate shown in FIG. 1(b).

This sintering step may be performed successively after the debindering step. For example, using a continuous furnace, the green sheet laminate with a cavity formed therein is held at a temperature in the range of 200° C. or more and for 120 min or more and 600 min or less, and then held at a temperature in the range of 850° C. or more and 940° C. or less for 100 min or more and 180 min or less. Moreover, the holding temperature may be constant or may be varied. For example, the green sheet laminate 290 may be heated up to 200° C. and slowly heated up to 600° C., and then it may be heated to a temperature in the range of 850° C. or more and 940° C. or less. By successively performing the two steps, it is possible to shorten the manufacturing process.

When the green sheet laminate forms a large substrate that is a collection of multi-layer ceramic substrates 101, it is possible to obtain a plurality of multi-layer ceramic substrates by severing the large substrate, obtained by sintering, along separation grooves.

According to the method of producing a multi-layer ceramic substrate of the present embodiment, the thickness of the thermal expansion layer increases when heated, thereby displacing a portion of the green sheet laminate to be the cavity. The thermal expansion layer is thin before being heated, and it does not inhibit the adhesion between two ceramic green sheets when it is interposed between the ceramic green sheets. Therefore, it is possible to prevent ceramic green sheets from being shifted from each other when laminating the ceramic green sheets together to form a green sheet laminate and when forming a groove along the outline of the cavity. Moreover, it is possible to maintain a high formability of the green sheet laminate, e.g., it is possible to increase the adhesion between ceramic green sheets in the green sheet laminate and to ensure a good flatness of the cavity bottom surface.

The thickness of the thermal expansion layer increases significantly, thereby displacing the portion to be the cavity of the green sheet laminate. Therefore, even if the groove along the outline of the cavity is not completely connected to the thermal expansion layer, the shear stress due to the displacement causes a crack in the ceramic green sheet, thereby separating the portion to be the cavity from the green sheet laminate. The shear stress is unlikely to cause a crack in an unintended portion. Therefore, even with an alignment error taken into account, possible to possible to reliably separate the portion to be the cavity from the green sheet laminate with a high yield. Moreover, s possible to check whether the cavity has been formed properly before sintering, it is possible to exclude defective products before sintering. Thus, it is possible to provide a method of producing a multi-layer ceramic substrate with a good mass productivity and with a high yield.

By selecting a material that disappears at a temperature for the debindering step or the wintering step, most the thermal expansion layer disappears in these steps. Therefore, it is possible to prevent the decrease in flatness or the cleanliness of the cavity bottom surface due Impurity remaining on the bottom surface of the cavity. Thus, it is possible to obtain clean electrode surfaces and thermal vias. Since the cavity is maintained even in the sintered multi-layer ceramic substrate, it is possible to accommodate a semiconductor device, or the like, cleaning the residue. With a semiconductor device accommodated in the cavity, it is possible to achieve a high degree of integration and a low profile for multi-layer ceramic substrates.

### Other Embodiments

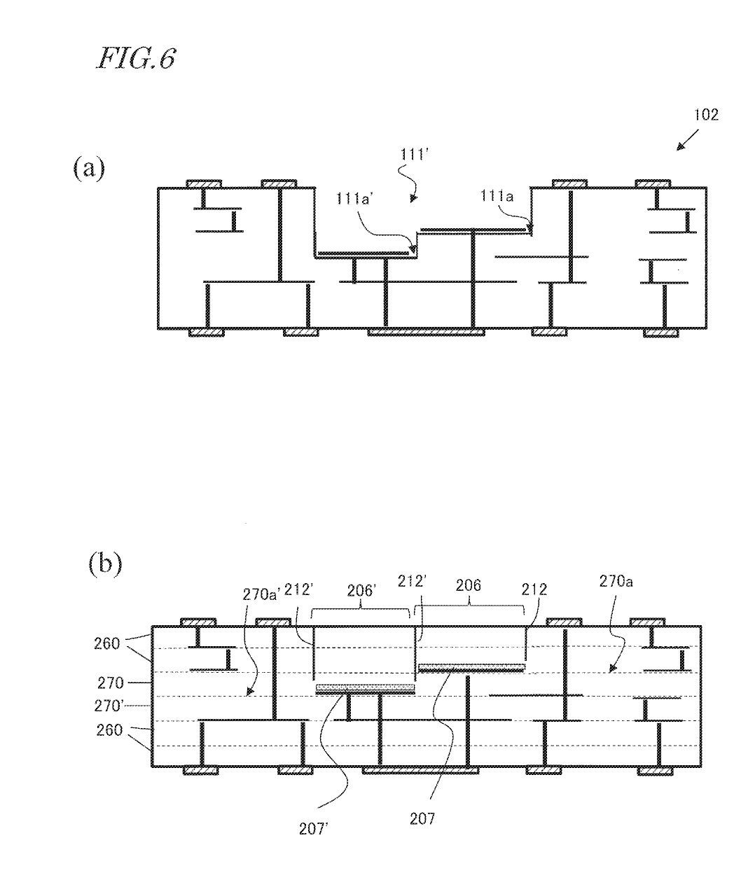

While the embodiment described above is directed to a multi-layer ceramic substrate whose cavity has one flat bottom surface, a multi-layer ceramic substrate may include a plurality of cavities having the same depth, or may include a plurality of cavities having different depths. A multi-layer ceramic substrate may include a cavity having a plurality of bottom surfaces of different heights. For example, as shown in FIG. 6(a), a multi-layer ceramic substrate 102 may include a cavity 111′ having a first bottom portion 111a and a second bottom portion 111e at different heights. While the second bottom portion 111e is located deeper than the first bottom portion 111a in the cavity 111′ in the present embodiment, the second bottom portion 111e may be located shallower than the first bottom portion 111a.

As shown in FIG. 6(b), first, there are prepared a first ceramic green sheet 270 with a thermal expansion layer 207 arranged in the region 206 to be the first bottom portion 111a and a third ceramic green sheet 270′ with a thermal expansion layer 207′ arranged in a region 206′ to be the second bottom portion 111a′. Then, the first ceramic green sheet 270 and the third ceramic green sheet 270′ are arranged so that the primary surface 270a of the first ceramic green sheet 270 and a primary surface 270a′ of the third ceramic green sheet 270′ are at the levels of the first bottom portion 111a and the second bottom portion. 111a′ when forming the green sheet laminate. A groove 212′ and the groove 212 are formed at positions to be the side surface of the cavity 111′. Moreover, it is preferred that the groove 212′ is provided at the boundary between the region. 206 and the region 206′ so as to reach the vicinity of the primary surface 270a′ of the third ceramic green sheet 270′. The multi-layer ceramic substrate 102 can be manufactured with the other conditions being equal to those of the method described above. In this case, the thickness of the thermal expansion layer 207 as expanded may be different from the thickness of the thermal expansion layer 207′ as expanded.

While the cavity 111′ has one first bottom portion 111a and one second bottom portion 111a′ in FIG. 6, the multi-layer ceramic substrate may include a cavity having three or more bottom portions at different levels. In such case, three first ceramic green sheets 270 including thermal expansion layers at different positions from each other are prepared, and these three first ceramic green sheets 270 are arranged in the green sheet laminate so as to be at different levels from each other.

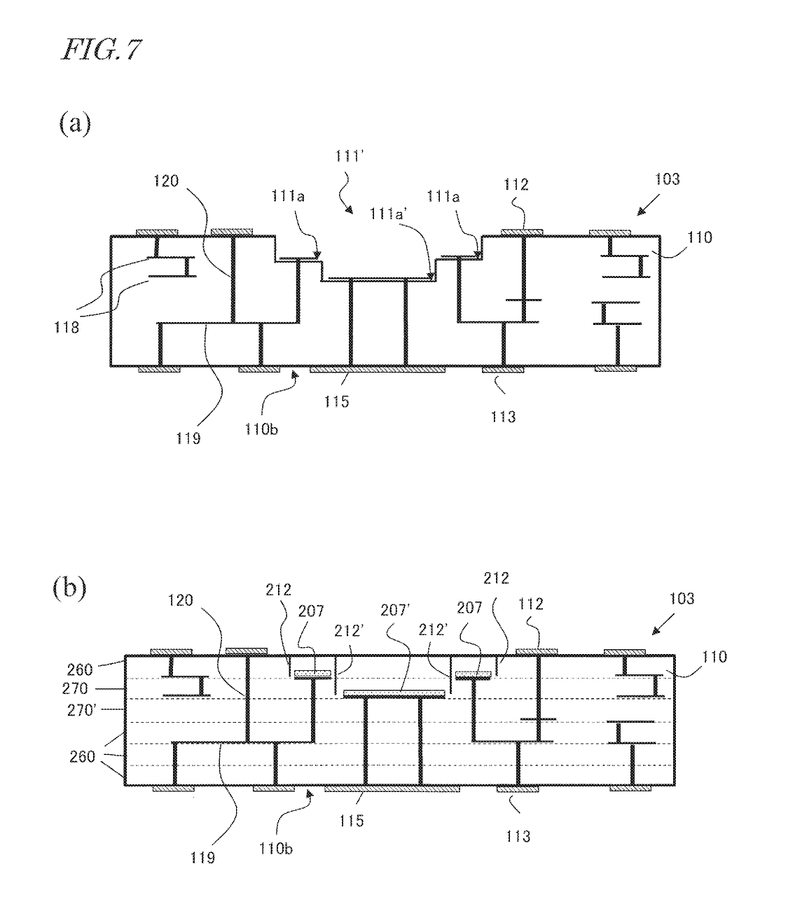

Moreover, as shown in FIG. 7(a), in a multi-layer ceramic substrate 103, the cavity 111′ may have one second bottom portion 111a′, and two first bottom portions 111a located with the second bottom portion 111e sandwiched therebetween. In such a case, as shown in FIG. 7(b), there are prepared a first ceramic green sheet 270 including two thermal expansion layers 207 arranged at positions corresponding to the two first bottom portions 111a, and a third ceramic green sheet 270′ including a thermal expansion layer 207′ arranged at a position corresponding to the second bottom portion 111a′. The first green sheet. 270 and the third ceramic green sheet 270′ are laminated together so as to be at different each other.

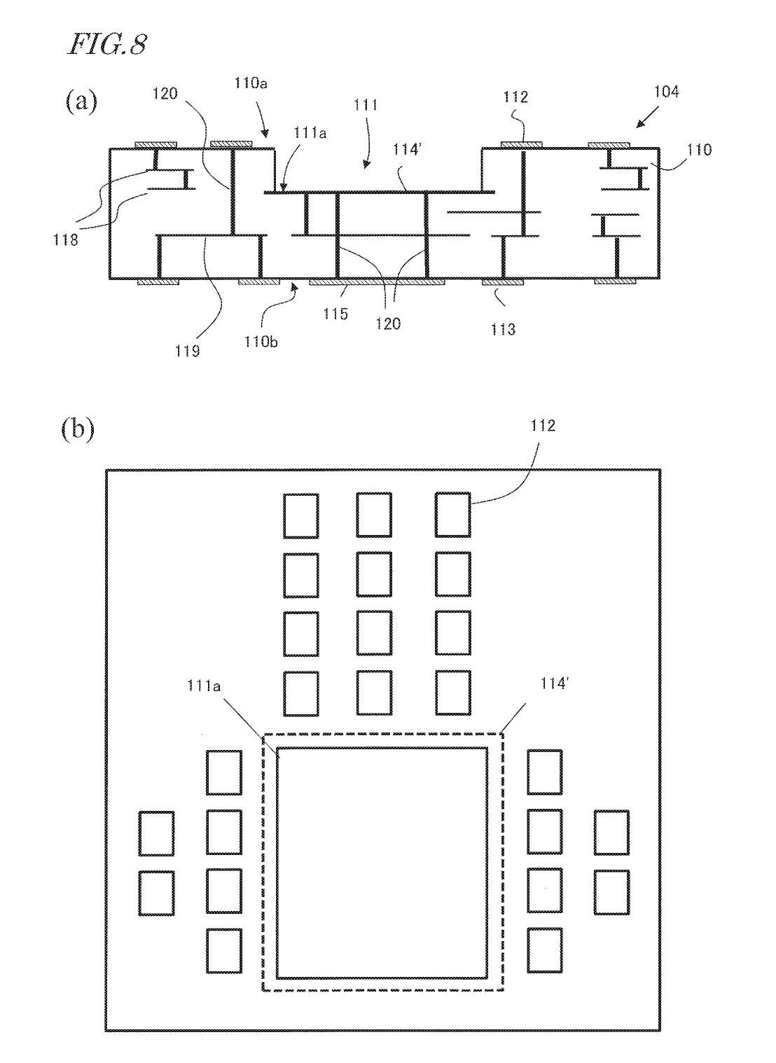

In the embodiment described above, the electrode 114 located on the bottom portion 111a of the cavity 111 is smaller than the bottom portion 111a. However, the electrode 114 may be larger than the bottom portion 111a. FIG. 8(a) and FIG. 8(b) are a cross-sectional view and a plan view, respectively, of a multi-layer ceramic substrate 104. The multi-layer ceramic substrate 104 includes an electrode 114′ that is larger than the bottom portion 111a of the cavity 111. Like the embodiment shown in FIG. etc., the conductive via 120 is connected to the electrode 114′, and the conductive via 120 is connected to the heat-radiating electrode 115 provided on the lower surface 110b of the ceramic sinter 110, for example. The electrode 114′ is used as a heat-radiating electrode or a ground electrode for an electronic component arranged the cavity 111, for example.

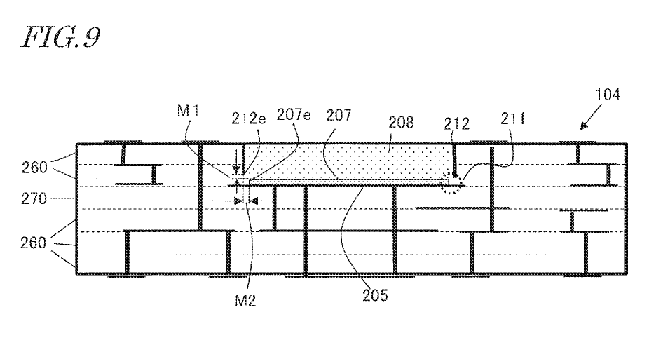

FIG. 8(a) shows the electrode 114′ as if a portion thereof that is exposed as the bottom portion 111a of the cavity 111 and a portion thereof that is buried in the ceramic sinter 110 were forming the same plane. However, as shown in FIG. 9, during the manufacturing process the multi-layer ceramic substrate 104, the thermal expansion layer 207 is arranged only on a portion the cavity 111) of the electrode pattern 205 to be the electrode 114′. Therefore, ng the sheet laminate, a portion of the electrode pattern 205 to be the cavity 111 may possibly be depressed by being prepared by the thermal expansion layer 207. In such a case, the electrode 114′ of the multi-layer ceramic substrate 104 may include a depressed portion in an area where it is exposed as the bottom portion 111a of the cavity 111.

With the multi-layer ceramic substrate 104, the groove 212 for forming the cavity 111 is located above the electrode pattern 205 during manufacturing process, as shown in FIG. 9.

Therefore, when at least one of the margin M1 and the margin M2 is provided between the end portion 207e of the thermal expansion layer 207 and the bottom portion 212e of the groove 212, a shear stress acts on the portion 211 due to the expansion of the thermal expansion layer 207, and a crack occurring from the bottom portion 212e of the groove 212 is likely to extend straight. This is because the upper surface of the electrode pattern 205 and the ceramic green sheet, which are made of different materials, are likely to peel off from each other at the boundary therebetween to release the stress. Thus, with the multi-layer ceramic substrate 104, the burrs 208b are unlikely to occur on the bottom portion 111a of the cavity 111, and the burrs 208b, even if produced, will be small.

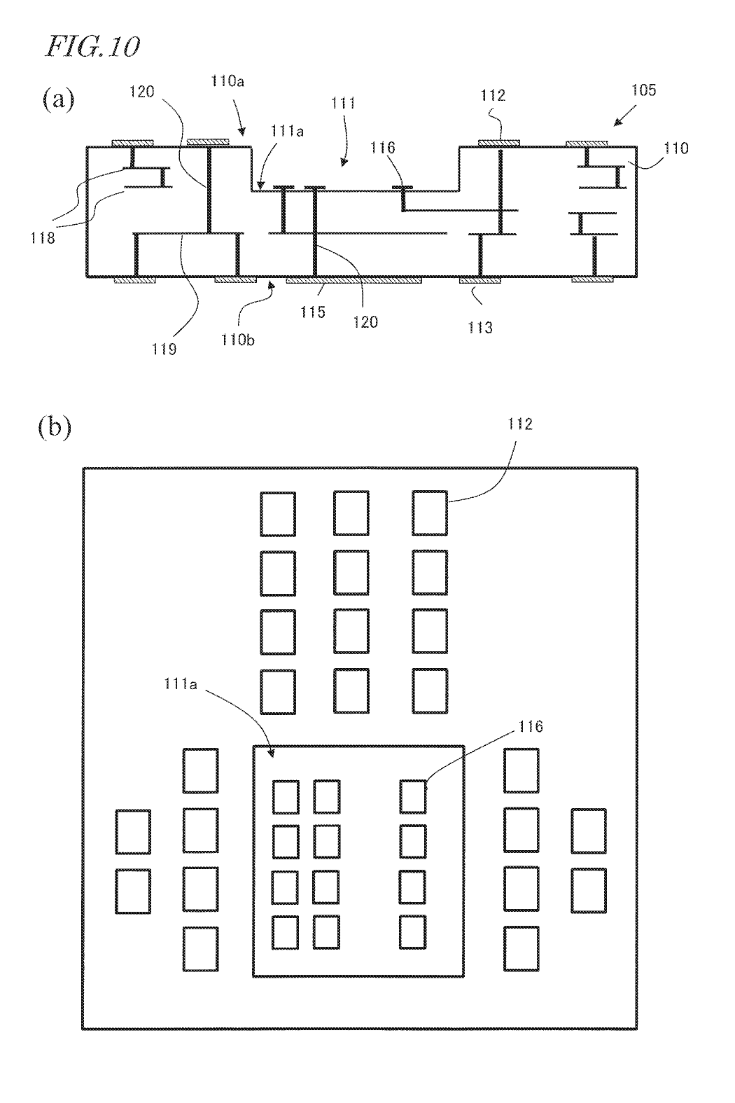

FIG. 10(a) and FIG. 10(b) are a cross-sectional view and plan view, respectively, of a multi-layer ceramic substrate 105. The multi-layer ceramic substrate 105 includes a plurality of pad electrodes 116 on the bottom portion 111a of the cavity 111. The conductive vias 120 are connected to the pad electrodes 116, and the conductive vias 120 are connected to the wiring pattern 119, the passive element pattern 118, etc.

With the multi-layer ceramic substrate 105, an electronic component such as an integrated circuit can be connected by flip-chip bonding in the cavity 111. Therefore, there is no need to connect bonding wires to an active element accommodated in the cavity 111 as shown in FIG. 1, etc., and it is possible to reduce the height of the multi-layer ceramic substrate 105 with an electronic component mounted thereon. Moreover, another electronic component, another multi-layer ceramic substrate, or the like, can be arranged on the multi-layer ceramic substrate 105.

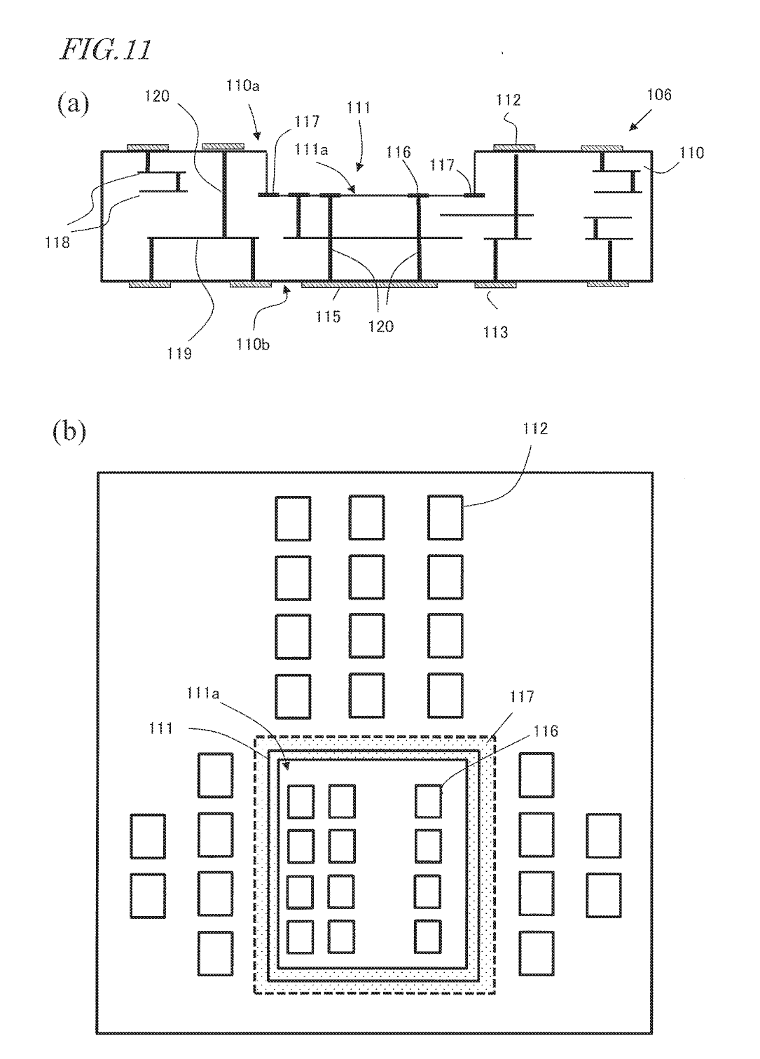

FIG. 11(a) and FIG. 11(b) are a cross-sectional view and a plan view, respectively, of a multi-layer ceramic substrate 106. The multi-layer ceramic substrate 106 is different from the multi-layer ceramic substrate 104 shown in FIG. 10 in that the multi-layer ceramic substrate 106 further includes an electrode 117 that is located below the side surface of the cavity 111, extending along the periphery of the bottom portion 111a. As described above with reference to FIG. 9, when the multi-layer ceramic substrate 106 is manufactured, the groove 212 for forming the cavity 111 is located over the pattern of the electrode 117. Therefore, with the multi-layer ceramic substrate 106, the burrs 208b are unlikely to occur on the bottom portion 111a of the cavity 111, and the burrs 208b, even if produced, will be small.

Note that while the cavity forming step is performed after the step of expanding the thermal expansion layer in the embodiment described above, the cavity forming step may be performed during the step of expanding the thermal expansion layer or during the debindering step. During the expansion step or during the debindering step, as used herein, means that the cavity is formed while the green sheet laminate is held under the condition for the expansion step or the condition for the debindering step.

### EXAMPLES

The results of conducting experiments for the method of producing a multi-layer ceramic substrate of the present embodiment will now be described.

### Example 1

Characteristics of Thermal Expansion Layer

A thermal expansion layer paste as prepared, and it was confirmed that the thermal expansion layer exhibited a thickness change sufficient for the formation of the cavity at a desired temperature. Ceramic green sheets were produced by forming a ceramic material including Al, Si and Sr as its main components and Ti, Bi, Cu, Mn, Na and K as its sub-components into a sheet shape.

Thermally-expansive microcapsules (F, FN series from Matsumoto Yushi-Seiyaku Co., Ltd.) having average particle sizes and expansion start temperatures shown in Table 1 were prepared as thermal expansion materials. TMC-108 (from Tanaka Kikinzoku Kogyo K.K.) was used as a vehicle, and the thermally-expansive microcapsules and the vehicle were mixed ether at weight ratio of 1:9 produce a paste. The obtained paste was applied on a PET film so that the thickness as dried is about 0.1 mm and then dried, thereby obtaining samples of thermal expansion layers. A plurality of samples were produced using the thermal expansion materials of Samples 1 to 3. The produced samples were heated at a temperature of 70° C. to 130° C., and the change in the thickness of each sample was measured by using a micrometer, and the thickness change of the sample was calculated. Specifically, the thickness change (expansion factor) a with respect to the thickness before being heated was calculated as a numerical value by the following formula, where t₁ is the thickness before being heated and t₂ is the thickness after being heated.

α=t₂/t₁

TABLE 1

| | | Expansion start |
|---|---|---|
| Samples | Particle size (μm) | temperature (° C.) |
| Sample 1 | 6-10 | 100-110 |
| Sample 2 | 9-15 | 90-100 |
| Sample 3 | 20-30 | 115-125 |

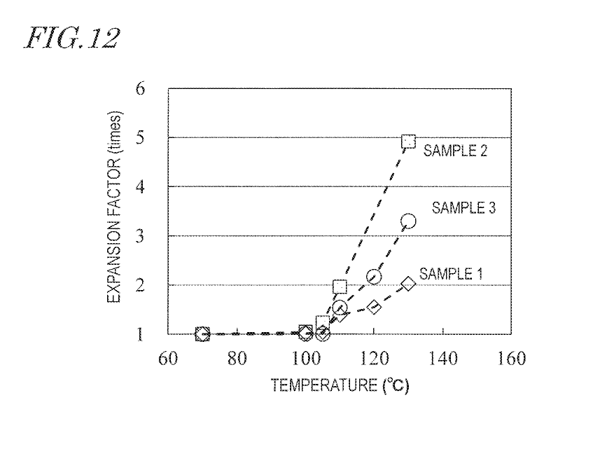

The results are shown in FIG. 12. The horizontal axis represents the temperature at which heating was done, and the vertical axis represents the thickness change (expansion factor) with respect to the thickness before being heated.

It was found that each sample expands at about 100° C. to about 110° C., and the thickness thereof increases by a factor of about 2 to about 5 at 130° C. The temperature range is between the temperature of the final pressure-bonding and the temperature of the debindering in the manufacturing process of the multi-layer ceramic substrate.

### Example 2

Formation of Cavity

The amount of thickness change of the thermal expansion layer that is needed for forming a cavity without forming a groove was examined. Ceramic green sheets having a thickness of 110 μm were prepared, and six of them were layered together to form a ceramic green sheet laminate. The size of the cavity was 25 mm long, 25 mm wide and 0.1 mm deep. For the thermal expansion layer, the thermal expansion layer paste of Sample 1 described above was applied on a ceramic green sheet by using a screen printing method. The thickness of the thermal expansion layer was 0.01 mm, as measured by observing the cross section of the produced sheet laminate with a microscope. In order to vary the amount of thickness change, the heating temperature when expanding the thermal expansion layer was adjusted in accordance with FIG. 12. A plurality of samples were produced to evaluate the percentage with which the portion corresponding to the cavity was extracted properly. The results are shown in Table 2. Herein, the percentage of proper extraction refers to the percentage with which the portion corresponding to the cavity was extracted properly because of the thickness change of the thermal expansion layer. That is, for the following results, a study was conducted to determine a predetermined range of the amount of thickness change before and after heating the thermal expansion layer for forming the cavity, without forming, in the green sheet laminate, a groove that has the depth of the cavity and that defines the outline of the cavity.

TABLE 2

| | Amount of | | | |
|---|---|---|---|---|
| Heating | thickness change | Number of | Number of | Percentage of |
| temperature | (expansion | successful | samples | successful |
| (° C.) | factor) (times) | extractions | tested | extraction (%) |
| 70 | 1.00 | 0 | 50 | 0 |
| 100 | 1.01 | 0 | 50 | 0 |
| 110 | 1.5 | 0 | 3 | 0 |
| 120 | 2.2 | 1 | 3 | 33.33 |
| 130 | 3.7 | 80 | 80 | 100 |

It can be seen from Table 2 that if the amount of thickness change is about 2.2, it is possible to form the cavity by virtue of the thickness change of the thermal expansion layer with a yield of about ⅓. It can also be seen that if the amount of thickness change is 3.7 times, it is possible to reliably form the cavity. It can be seen from these results that the thickness of the thermal expansion layer preferably increases by a factor of 2 or more and 4 or less by being heated.

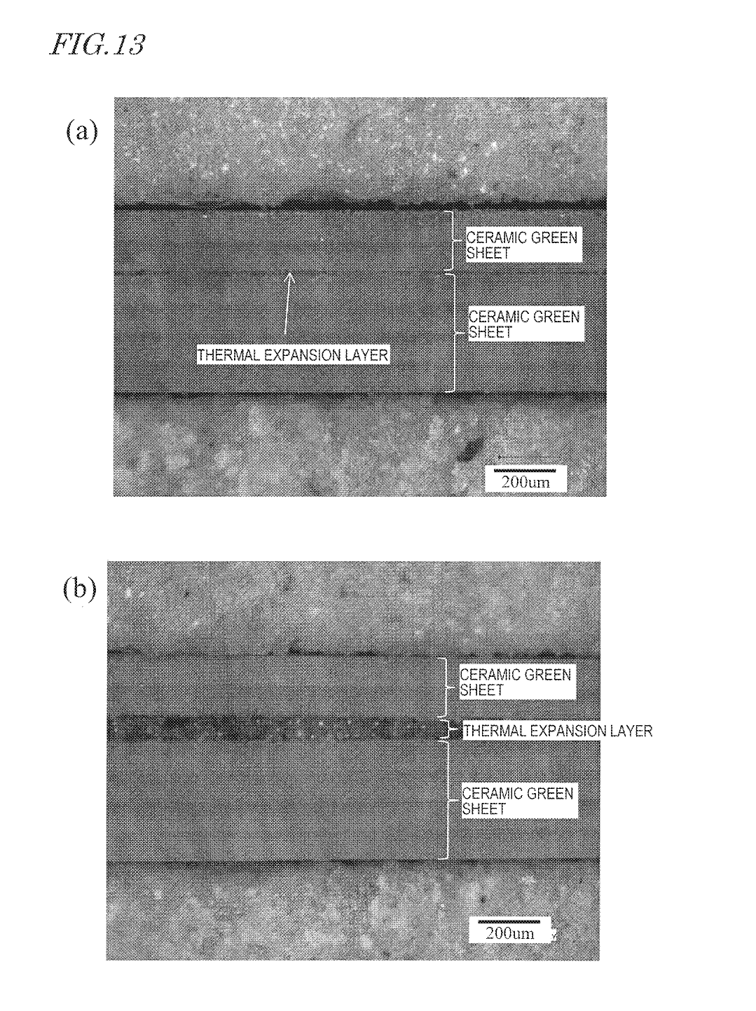

FIGS. 13(a) and 13(b) are optical microscopic images before and after the thermal expansion layer is heated, respectively, for a sample that was obtained by laminating and pressure-bonding six layers of ceramic green sheets each having a thickness of 110 μm, wherein the depth of the cavity was 0.2 mm and the amount of thickness change was 6 times. While it can be seen from FIG. 13(a) that the thickness the thermal expansion layer before being heated was about 10 μm, it can be seen from FIG. 13(b) that the thickness of the thermal expansion layer after being heated was about 50 μm.

### Example 3

Manufacturing Multi-Layer Ceramic Substrate

A multi-layer ceramic substrate was manufactured, in which a cavity was formed under the following condition.

First, a ceramic material including Al, Si and Sr as its main components and Ti, Bi, Cu, Mn, Na and K as its sub-components was prepared. A plurality of ceramic green sheets were obtained as described above using the ceramic material prepared.

Next, via holes were formed in the obtained ceramic green sheets by using a laser puncher, and screen printing was used to fill the via holes with a conductive paste and to form wiring patterns. A material including Ag as a conductive material was used as the conductive paste. Moreover, a thermal expansion layer was formed in a region of the first ceramic green sheet to be the bottom surface of the cavity. The thermal expansion layer was formed by a screen printing method using a thermal expansion layer paste so that the thickness as dried would be 10 μm. In the thermal expansion layer paste, thermally-expansive microcapsules (F, FN series from Matsumoto Yushi Kogyo) were cleaned with ammonium fluoride and used as the thermal expansion material, and acrylic beads (from Sekisui Plastics Co., Ltd.) were added at the same time as the unevenness improving material for the cavity bottom surface.

The obtained first and second ceramic green sheets were successively laminated together by repeating the operation of preliminary pressure-bonding one of the first and second ceramic green sheets and peeling off the carrier film to obtain a green sheet laminate including 4 to 20 layers of ceramic green sheets, specifically, seven layers of ceramic green sheets, each having a thickness of 80 μm, laminated together. Then, the green sheet laminate was subjected to final pressure-bonding at 17 MPa being heated to 85° C.

In the green sheet having been subjected to the final pressure-bonding, a groove having a depth of 180 μm was formed along the outline of the portion the cavity using a chisel blade shape.

Next, the thermal expansion layer of the grooved green sheet laminate was heated to 130° C. and held for 15 min. Thus, the thickness of the thermal expansion layer was increased and the portion to be the cavity was displaced. The displaced portion to be the cavity was easily extracted by a tape, thereby forming the cavity. Then, grooves to be used for separation after sintering were formed.

The green sheet laminate with the cavity formed therein and with separation grooves formed therein was subjected to the debindering step and the sintering step in the range of conditions described above by using a continuous furnace. Thus, a multi-layer ceramic substrate having a cavity was obtained. It was confirmed that although a part of the expanded thermal expansion layer remained on the bottom portion of the cavity when the cavity was formed in the green sheet laminate, most of it had disappeared after the sintering step. Moreover, even traces of thermal expansion layer microcapsules did not remain on the bottom surface of the cavity after sintering. With the multi-layer ceramic substrate obtained through the steps described above, it is possible to form the cavity using substantially the same steps as those of existing multi-layer ceramic substrates, exhibiting a good mass productivity.

### Example 4

Formation of Samall Cavity

The thickness of the co-fired multi-layer ceramic substrate and the depth of the cavity were varied so as to check whether a small cavity can be produced. Using a production method similar to Example 3, multi-layer ceramic substrates were produced whose thicknesses would be 325 μm, 650 μm and 1300 μm, after being fired. The size of the cavity was 1.3 mm×1.3 mm, 2.3 mm×2.3 mm. Whether the cavity can be formed was checked while setting the depth of the cavity to 100 μm, 150 μm, 200 μm, 250 μm and 300 μm. The results are shown in Table 3.

TABLE 3

| | | Substrate Thickness (μm) | | | | | |
|---|---|---|---|---|---|---|---|
| | cavity | 325 | | 650 | | 1300 | |
| | size (mm) | 1.3 × 1.3 | 2.3 × 2.3 | 1.3 × 1.3 | 2.3 × 2.3 | 1.3 × 1.3 | 2.3 × 2.3 |
| Cavity | 100 | ∘ | ∘ | ∘ | ∘ | ∘ | ∘ |
| depth | 150 | ∘ | ∘ | ∘ | ∘ | ∘ | ∘ |
| (μm) | 200 | x | x | Δ | ∘ | Δ | ∘ |
| | 250 | x | x | Δ | ∘ | Δ | ∘ |
| | 300 | | | Δ | ∘ | Δ | ∘ |

In Table 3, “o” indicates that a cavity having a desirable shape was formed. “Δ” indicates that the extraction of the cavity was not easy, and the shape of the cavity formed did not have a sufficiently good finish. “x” indicates that a crack occurred on the bottom portion of the cavity.

It was found from the results shown in Table 3 that even small cavities whose planar shapes are 1.3 mm×1.3 mm and 2.3 mm×2.3 mm could be formed. It was also found that it was possible to form a cavity without causing a crack on the bottom portion the depth of the cavity was ½ or less of the thickness of the multi-layer ceramic substrate.

### Example 5

Determination of Margin and Size of Burr

As shown in 4(b), the size in the horizontal direction of the burrs 208b produced on the bottom portion 111a of the cavity 111 was examined when producing a multi-layer ceramic substrate while setting, to various values, the margin M1 in the vertical direction and the margin M2 in the horizontal direction between the end portion of the groove 212 and the end portion of the thermal expansion layer 207.

A multi-layer ceramic substrate that includes a cavity having a 2.3 mm by 2.3 mm rectangular opening and has an electrode on the bottom portion of the cavity as shown in FIG. 8 (hereinafter, “multi-layer ceramic substrate with an electrode”) and a multi-layer ceramic substrate that includes a cavity having a 2.3 mm by 2.3 mm rectangular opening and has no electrode on the bottom portion of the cavity (hereinafter, a “multi-layer ceramic substrate without an electrode”) were produced. The depths of the cavities were 200 μm and 300 μm. The results are shown in Tables 4 and 5. The margin M1 in the vertical direction and the margin M2 in the horizontal direction are as shown in Tables 4 and 5. The size of the burr 208b represents the sum of the lengths of the burrs 208b on the opposite sides for the width direction and for the longitudinal direction, and Tables 4 and 5 show an average value of the burrs 208b in the width direction and the longitudinal direction. The margin M1 being −50 indicates an over-cut, i.e., formation of a groove that is 50 μm deeper than the thermal expansion layer. Such samples for the multi-layer ceramic substrate with an electrode were not produced because the electrode would then be severed.

TABLE 4

| Substrate type | |
|---|---|
| Multi-layer | Multi-layer |
| ceramic substrate | ceramic substrate |
| with electrode | without electrode |

| Margin M2 (μm) | | 75 | 50 | 75 | 50 |
|---|---|---|---|---|---|
| Margin | 50 | 116 | 127 | 160 | 120 |
| M1 (μm) | 25 | 74 | 70 | 155 | 106 |
| | 0 | 86 | 69 | 150 | 109 |
| | −50 | — | — | 120 | 111 |

TABLE 5

| Substrate type | |
|---|---|
| Multi-layer | Multi-layer |
| ceramic substrate | ceramic substrate |
| with electrode | without electrode |

| Margin M2 (μm) | | 75 | 50 | 75 | 50 |
|---|---|---|---|---|---|
| Margin | 50 | 230 | 194 | 195 | 190 |
| M1 (μm) | 40 | 136 | 160 | 154 | 151 |
| | 0 | 53 | 56 | 135 | 90 |
| | −50 | — | — | 160 | 126 |

It can be seen from the results of Table 4 and Table 5 that the burrs 208b can generally be made smaller with a multi-layer ceramic substrate with an electrode. There is also a tendency that the burrs 208b become longer as the cavity is deeper (Table 5). It can be seen from these results that it is possible to adjust the length of the burrs 208b by varying the margins M1 and M2. Specifically, it was found that it is possible to make the length of the burrs to be 250 μm or less by adjusting the margins M1 and M2, and with a multi-layer ceramic substrate with an electrode, it is possible to make the length of the burrs 208b to be about 100 μm or less by setting suitable margins M1 and M2. Also, it was found that with a multi-layer ceramic substrate without an electrode, it is possible to make the length of the burrs 208b to be about 150 μm or less by setting suitable margins M1 and M2.

### INDUSTRIAL APPLICABILITY

The method of producing multi-layer ceramic substrate the present disclosure can suitably be used in a multi-layer ceramic substrate having a cavity that is suitable for various applications.

### REFERENCE SIGNS LIST

101: Multi-layer ceramic substrate
110: Ceramic sinter
110a: Upper surface
110b: Lower surface
111: Cavity
111a: Bottom portion
112, 113, 114, 115, 117: Electrode
118: Passive element pattern
119: Wiring pattern
120: Conductive via
151: Semiconductor IC chip
152: Capacitor
153: Bonding wire
200: Ceramic green sheet
201: Via hole
202: Conductive paste
203: Wiring pattern
204: Passive element pattern
206: Region
207: Thermal expansion layer
208: Portion to be cavity
208b: Burrs
205, 209, 210: Electrode pattern
212: Groove
250: Carrier film
260: Second ceramic green sheet
270: First ceramic green sheet

1. A method of producing a multi-layer ceramic substrate, the method comprising the steps of:
(A) preparing a first ceramic green sheet with a thermal expansion layer arranged thereon, and at least one second ceramic green sheet with no thermal expansion layer arranged thereon;
(B) laminating the first and second ceramic green sheets with the thermal expansion layer sandwiched therebetween, thereby obtaining a green sheet laminate;
(C) pressure-bonding together the first ceramic green sheet and the at least one second ceramic green sheet of the green sheet laminate;
(D) heating and thereby expanding the thermal expansion layer at least in a thickness direction in the pressure-bonded green sheet laminate;
(E) extracting a portion of the green sheet laminate that has been displaced by the expansion of the thermal expansion layer, thereby forming a cavity in the green sheet laminate; and
(F) sintering the green sheet laminate with the cavity formed therein.

2. The method of producing a multi-layer ceramic substrate according to claim 1, wherein in the step (D), the thermal expansion layer is held at a temperature higher than a temperature for pressure-bonding in the step (C).

3. The method of producing a multi-layer ceramic substrate according to claim 1, wherein the thermal expansion layer includes a thermal expansion material whose thickness increases by a factor of 2 or more by being heated.

4. The method of producing a multi-layer ceramic substrate according to claim 1, wherein the thermal expansion layer is a layer of a paste including thermally-expansive microcapsules made of a thermoplastic resin that encapsulate a hydrocarbon that is in liquid form at normal temperature.

5. The method of producing a multi-layer ceramic substrate according to claim 1, further comprising, between the step (C) and the step (D), a step of forming, in the green sheet laminate, a groove that has a depth of the cavity of the green sheet laminate and defines an outline of the cavity.

6. The method of producing a multi-layer ceramic substrate according to claim 1, wherein the thermal expansion layer is removed in the step (E).

7. The method of producing a multi-layer ceramic substrate according to claim 1, wherein:
in the step (A),
a third ceramic green sheet with another thermal expansion layer arranged thereon is prepared in a region different from the first ceramic green sheet;
in the step (B), the first to third ceramic green sheets are laminated together so that the thermal expansion layers are sandwiched therebetween, thereby obtaining the green sheet laminate;
in the step (D),
the other thermal expansion layer is heated to be expanded at least in the thickness direction; and
in the step (E),
a portion of the green sheet laminate that has been displaced by the expansion of the other thermal expansion layer is extracted.

8. The method of producing a multi-layer ceramic substrate according to claim 1, further comprising, between the step (E) and the step (F), a step (G) of removing a binder from the green sheet laminate.

9. The method of producing a multi-layer ceramic substrate according to claim 8, wherein in the step (D), the thermal expansion layer is held at a temperature that is higher than a temperature for pressure-bonding in the step (C) and lower than a temperature for binder removing in the step (G).

10. The method of producing a multi-layer ceramic substrate according to claim 1, wherein in the step (A), at least one of the first ceramic green sheet and the second ceramic green sheet includes a pattern to be internal wiring, an inductor, a condenser, a stripline or an internal resistor.

11. The method of producing a multi-layer ceramic substrate according to claim 1, wherein in the step (A), the first ceramic green sheet further includes a conductor pattern located between the thermal expansion layer and the first ceramic green sheet.

12. The method of producing a multi-layer ceramic substrate according to claim 1, wherein in the step (A), at least one of the first ceramic green sheet and the second ceramic green sheet further includes a via hole and a conductive paste that fills the via hole.
